(19) United States
(12) Patent Application Publication
(10) Pub. No.: US 2012/0139654 A1
(43) Pub. Date: Jun. 7, 2012

(54) FREQUENCY SYNTHESIZER

(75) Inventors: Atsushi OHARA, Shiga (JP); Hidetoshi YAMASAKI, Hyogo (JP)

(73) Assignee: PANASONIC CORPORATION, Osaka (JP)

(21) Appl. No.: 13/371,138

(22) Filed: Feb. 10, 2012

Related U.S. Application Data
(63) Continuation of application No. PCT/JP2011/002215, filed on Apr. 14, 2011.

(30) Foreign Application Priority Data
Jun. 21, 2010 (JP) 2010-140470

(51) Int. Cl. H03J 7/04

(52) U.S. Cl. 331/36 C

(57) ABSTRACT

A frequency synthesizer includes a control circuit configured to generate a digital control signal; and a digitally controlled oscillator of which oscillation frequency changes according to the generated digital control signal. The control circuit includes an operational circuit configured to divide an integer portion of a numerical value representing a phase difference between a reference signal and an oscillation frequency signal of the digitally controlled oscillator into high-order bits and low-order bits including a redundant bit as an MSB, and two encoders configured to encode the high-order bits and the low-order bits to generate control signals. The digitally controlled oscillator includes two capacitive element groups having capacitance values controlled by the control signals. The oscillation frequency of the digitally controlled oscillator changes according to a total capacitance value of the two capacitive element groups.

### CROSS-REFERENCE TO RELATED APPLICATION

This is a continuation of PCT International Application PCT/JP2011/002215 filed on Apr. 14, 2011, which claims priority to Japanese Patent Application No. 2010-140470 filed on Jun. 21, 2010. The disclosures of these applications including the specifications, the drawings, and the claims are hereby incorporated by reference in their entirety.

### BACKGROUND

The present disclosure relates to frequency synthesizers, and more particularly to frequency synthesizers of which oscillation is controlled by digital values.

In recent years, with the development of miniaturization techniques of CMOS processes, research for achieving low voltage drive, reduction in characteristic variations, and miniaturization of circuits by replacing all or part of analog circuits with digital circuits has progressed. For example, there is an all-digital PLL frequency synthesizer including elements such as a phase comparator and a loop filter, which are all digitalized. This synthesizer includes a digitally controlled oscillator (DCO) of which frequency is controlled by discrete numerical value information (a digital value) in place of a voltage-controlled oscillator of which frequency can be controlled by an analog voltage. The synthesizer digitalizes the phase information of an oscillation frequency signal which is output from the digitally controlled oscillator, and feeds back the digitalized information to the digitally controlled oscillator via the phase comparator and the loop filter, thereby forming a phase-locked loop (see, for example, U.S. Pat. No. 6,734,741 and Japanese Patent Publication No. 2009-10599).

In general, a digitally controlled oscillator is configured as an LC oscillation circuit formed by coupling an inductor to a plurality of capacitive elements in parallel. Each of the capacitive elements is controlled by a digital control signal to have either one of a high capacitance value or a low capacitance value so that the digitally controlled oscillator oscillates at a desired frequency. In the digitally controlled oscillator with this configuration, it is necessary to increase the number of the capacitive elements together with a control bit number to make a frequency change in a one-bit control signal as small and constant as possible, and to expand an oscillation frequency range. However, the increase in the control bit number and the number of the capacitive elements increase the area occupied by control lines and the capacitive elements as well as parasitic capacitance. There is a frequency synthesizer which divides the integer portion of a numerical value representing the phase difference between a reference signal and an oscillation frequency signal of a digitally controlled oscillator into high-order bits and low-order bits in a ratio of weight of N:1, where N is an integer of two or more, controls first capacitive elements each having the minimum capacitance value with the low-order bits, and controls second capacitive elements each having the capacitance value, which is N times the capacitance value of the first capacitive element, with the high-order bits (see, for example, Japanese Patent Publication No. 2009-10599). Since this frequency synthesizer requires less capacitive element, the number of the control lines can be reduced. Moreover, since the area for forming a single second capacitive element is smaller than the area for forming N first capacitive elements, the circuit area can be reduced as a whole.

The present inventors found that a conventional frequency synthesizer has the following two problems.

The first problem is that, at carry or borrow occurring between the low-order bits and the high-order bits, a difference between device structures of the first and second capacitive elements tends to cause nonlinearity. In particular, when the frequency synthesizer locks at the carry/borrow boundary, a great phase error occurs in response to a slight output fluctuation to cause noise.

The second problem is that an advantage cannot be sufficiently obtained, when mounting a dynamic element matching (DEM) equalizing variations in the capacitive elements by selecting different combination of control lines for a same control value as appropriate. For example, assume that there are 31 capacitive elements controlled by five low-order bits. When the low-order bits are 5b01111, preferable 15 of the 31 capacitive elements are controlled to have high capacitance values and the rest elements are controlled to have low capacitance values, thereby obtaining a DEM effect. When the low-order bits are 5b00000 or 5b11111, all the 31 capacitive elements are controlled to have low capacitance values or high capacitance values, thereby obtaining no DEM effect. As such, depending on the low-order bits, no DEM effect is obtained to degrade linearity. Therefore, when the frequency synthesizer is used as a modulator temporally changing a frequency, noise characteristics may degrade.

### SUMMARY

The present invention provides a frequency synthesizer with a small circuit area and excellent linearity and noise characteristics.

A frequency synthesizer according to an example of the present invention includes a control circuit configured to generate a digital control signal; and a digitally controlled oscillator of which oscillation frequency changes according to the generated digital control signal. The control circuit includes an operational circuit configured to divide an integer portion of a numerical value representing a phase difference between a reference signal and an oscillation frequency signal of the digitally controlled oscillator into high-order bits and low-order bits including a redundant bit as an MSB, a first encoder configured to encode the high-order bits to generate a first control signal, and a second encoder configured to encode the low-order bits to generate a second control signal. The digitally controlled oscillator includes a first capacitive element group formed by coupling in parallel, a plurality of first capacitive elements which are switchable between high and low capacitance states, and having a capacitance value controlled by the first control signal, and a second capacitive element group formed by coupling in parallel, a plurality of second capacitive elements which are switchable between high and low capacitance states, and having a capacitance value controlled by the second control signal. The oscillation frequency of the digitally controlled oscillator changes according to a total capacitance value of the first and second capacitive element groups.

A frequency synthesizer according to another example of the present invention includes: a control circuit configured to generate a digital control signal; and a digitally controlled oscillator of which oscillation frequency changes according to the generated digital control signal. The control circuit includes an operational circuit configured to divide an integer portion of a numerical value representing a phase difference between a reference signal and an oscillation frequency signal of the digitally controlled oscillator into high-order bits and low-order bits and to generate a redundant bit, a first encoder configured to encode the high-order bits to generate a first control signal, and a second encoder configured to encode the low-order bits to generate a second control signal. The digitally controlled oscillator includes a first capacitive element group formed by coupling in parallel, a plurality of first capacitive elements which are switchable between high and low capacitance states, and having a capacitance value controlled by the first control signal, a second capacitive element group formed by coupling in parallel, a plurality of second capacitive elements which are switchable between high and low capacitance states, and having a capacitance value controlled by the second control signal, and a third capacitive element which is switchable between high and low capacitance states by the redundant bit. The oscillation frequency of the digitally controlled oscillator changes according to a total capacitance value of the first and second capacitive element groups and the third capacitive element. Where a weight of the high-order bits to the low-order bits is N, the operational circuit increments the low-order bits by N/2, decrements the high-order bits by 1, and sets the redundant bit to a value so that the third capacitive element is in the high capacitance state when the low-order bits may be lower than a lower limit, and decrements the low-order bits by N/2 and sets the redundant bit to a value so that the third capacitive element is in the high capacitance state when the low-order bits may be higher than an upper limit. Note that a ratio of a difference between a high capacitance value and a low capacitance value of each of the first capacitive elements to a difference between a high capacitance value and a low capacitance value of the third capacitive element is 2:1.

With these configurations, when the low-order bits exceed the lower limit or the upper limit due to a variation in the integer portion, the high-order bits are incremented or decremented by 1 and the low-order bits return to a value ranging from the lower limit to the upper limit. That is, once carry or borrow occurs between the high- and low-order bits, variations in the integer portion can be absorbed by the low-order bits to hardly cause further carry or borrow.

### BRIEF DESCRIPTION OF THE DRAWINGS

FIG. 1 is a configuration diagram of a frequency synthesizer according to a first embodiment.

FIG. 2 illustrates a main configuration of a digitally controlled oscillator according to the first embodiment.

FIG. 3 is a flow chart illustrating an example operation of an operational circuit according to the first embodiment.

FIGS. 4A and 4B are tables illustrating example control values according to a conventional configuration and the first embodiment.

FIG. 5 illustrates a main configuration of a digitally controlled oscillator according to a variation.

FIG. 6 is a flow chart illustrating an example operation of an operational circuit according to the variation.

FIGS. 7A and 7B are tables illustrating example control values according to the conventional configuration and the variation.

FIG. 8 is a flow chart illustrating an operation of an operational circuit according a first example.

FIG. 9 illustrates an example configuration of the operational circuit according to the first example.

FIG. 10 illustrates another example configuration of the operational circuit according to the first example.

FIG. 11 is a flow chart illustrating an operation of an operational circuit according a second example.

FIG. 12 illustrates an example configuration of the operational circuit according to the second example.

FIG. 13 is a flow chart illustrating an operation of an operational circuit according a third example.

FIG. 14 illustrates an example configuration of the operational circuit according to the third example.

FIG. 15 is a table illustrating example control values according to the second and third examples.

FIG. 16 is a configuration diagram of a frequency synthesizer according to a second embodiment.

FIG. 17 illustrates a main configuration of a digitally controlled oscillator according to the second embodiment.

FIG. 18 is a flow chart illustrating an example operation of an operational circuit according to the second embodiment.

FIGS. 19A and 19B are tables illustrating example control values according to the conventional configuration and the second embodiment.

### DETAILED DESCRIPTION

### First Embodiment

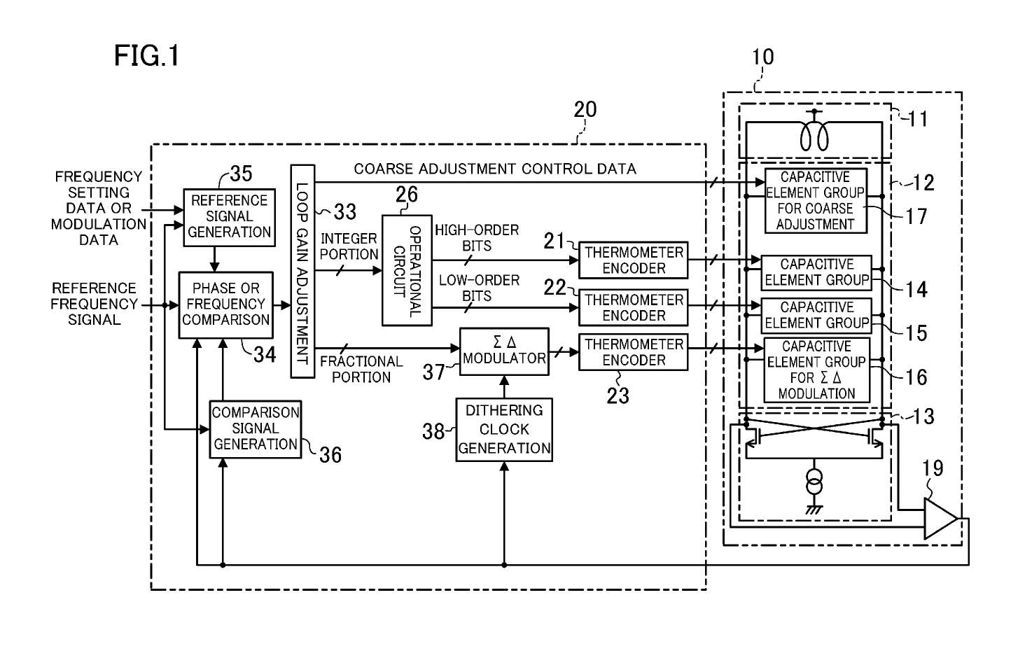

FIG. 1 illustrates a configuration of a frequency synthesizer according to a first embodiment. The frequency synthesizer according to this embodiment is a phase-locked loop (PLL) circuit which controls in a loop, an oscillation frequency of a digitally controlled oscillator (DCO) 10 with a control circuit 20. The DCO 10 is configured as an LC oscillation circuit including an inductor 11, a variable capacitance section 12, a negative resistance generation section 13, and an output amplifier 19. The oscillation frequency of the DCO 10 can be changed by changing the capacitance value of the variable capacitance section 12.

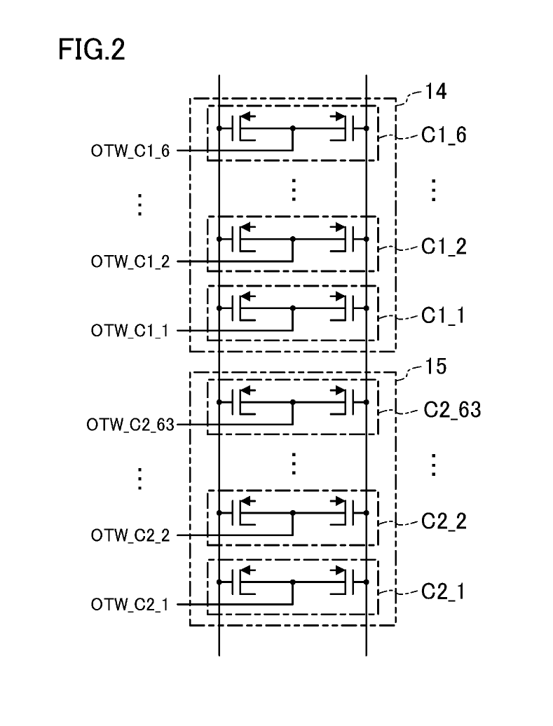

The variable capacitance section 12 includes a capacitive element group 14, a capacitive element group 15, a capacitive element group 16 for ΣΔ modulation, and a capacitive element group 17 for coarse adjustment. FIG. 2 illustrates a main configuration of the DCO 10. The capacitive element group 14 includes 6 capacitive elements C1_{—}1-C1_{—}6 coupled in parallel which are switched between a high capacitance value C_{H1} and a low capacitance value C_{L1} in response to control signals OTW_C1_{—}1-OTW_C1_{—}6, respectively. The capacitive element group 15 includes 63 capacitive elements C2_{—}1-C2_{—}63 coupled in parallel which are switched between a high capacitance value C_{H2} and a low capacitance value C_{L2} in response to control signals OTW_C2_{—}1-OTW_C2_{—}63, respectively. The ratio of a difference between C_{H1} and C_{L1} to a difference between C_{H2} and C_{L2} is N:1, where N is an integer of two or more. For example, where N=32, the total capacitance value of the capacitive element groups 14 and 15 can vary in 256 steps in which the difference between C_{H2} and C_{L2} is the minimum unit. The capacitive element C1 has a capacitance value, which is 32 times the capacitive element C2. On the other hand, since the single capacitive element is used, the occupied area does not simply increase 32 times, the advantage of sharing the surroundings other than the portion determining capacitance values and reducing the area for wirings. Therefore, the configuration of FIG. 2 largely reduces the circuit area as compared to the case where 255 capacitive elements C2 are formed,

Referring back to FIG. 1, in the DCO 10, a reference signal generation section 35 generates a reference signal from frequency setting data or modulation data and a reference frequency signal. A comparison signal generation section 36 divides the frequency of an output from the DCO 10 and integrates the output from the DCO 10 to generate a comparison signal. A signal compare section 34 receives the comparison signal and the reference signal, compares phases and/or frequencies of the signals, and outputs the comparison result according to the difference. A loop gain adjustment section 33 generates coarse adjustment control data for controlling the capacitive element group 17 for coarse adjustment, and fine adjustment control data for controlling the capacitive element groups 14 and 15 as well as the capacitive element group 16 for ΣΔ modulation based on the comparison result of the signal compare section 34 to obtain a proper loop gain. That is, the oscillation frequency of the DCO 10 is first roughly determined by the coarse adjustment control data, and then follows a target value using the fine adjustment control data so that the frequency synthesizer stably supplies a desired oscillation frequency signal.

The fine adjustment control data corresponds to the numerical value representing the phase difference between the reference signal and the oscillation frequency signal of the DCO 10. The numerical value includes an integer portion and a fractional portion. An operational circuit 26 divides the input integer portion into high-order bits and low-order bits in a ratio of weight of N:1, e.g., 32:1. The low-order bits include a redundant bit as an MSB. For example, if the integer portion is 8 bits, the high-order bits are 3 bits, and the low-order bits are 6 bits, which is the sum of 5 bits and 1 redundant MSB. That is, N is the value represented by 2′, where the bit width of the low-order bits is n+1. A thermometer encoder 21 converts the high-order bits to a thermometer code and generates a control signal OTW_C1 for controlling the capacitive element group 14. A thermometer encoder 22 converts the low-order bits to a thermometer code and generates a control signal OTW_C2 for controlling the capacitive element group 15.

A dithering clock generation section 38 generates a dithering clock signal from the oscillation frequency signal of the DCO 10. A ΣΔ modulator 37 is operated by the dithering clock signal and performs ΣΔ modulation of the fractional portion. A thermometer encoder 23 converts an output from the ΣΔ modulator 37 to a thermometer code and generates a control signal for controlling the capacitive element group 16 for ΣΔ modulation.

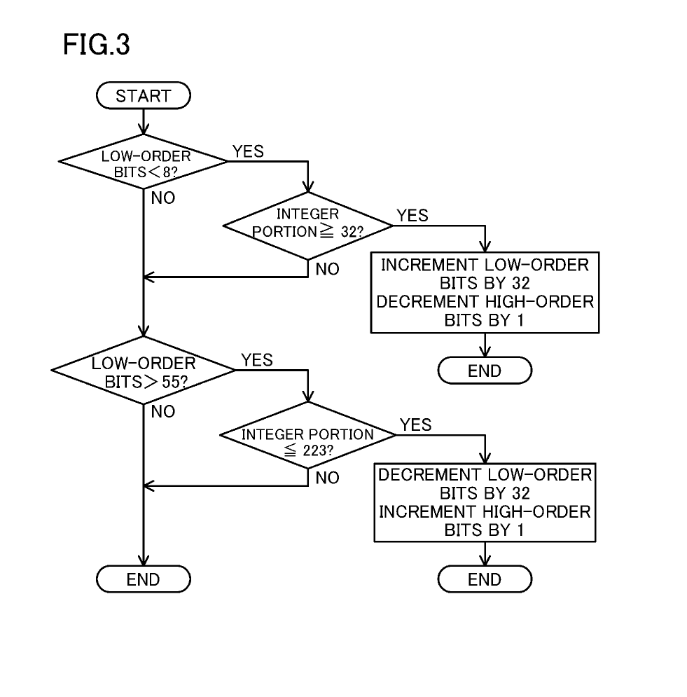

Next, an example operation of the operational circuit 26 will be described with reference to the flow chart of FIG. 3. The operational circuit 26 increments the low-order bits by N, i.e. 32, and decrements the high-order bits by 1 as borrow between the high- and low-order bits, when the low-order bits may be lower than a lower limit “8.” When the integer portion is lower than a lower limit “32,” the value of the high-order bits is the minimum value 3b000 and cannot be decremented. Thus, the operational circuit 26 performs the processing only when the integer portion is the lower limit “32” or higher. On the other hand, the operational circuit 26 decrements the low-order bits by N, i.e. 32, and increments the high-order bits by 1 as carry the between the high- and low-order bits, when the low-order bits may be higher than an upper limit “55.” When the integer portion is higher than an upper limit “223,” the value of the high-order bits is the maximum value 3b110 and cannot be incremented. Thus, the operational circuit 26 performs the processing only when the integer portion is the upper limit “223” or lower.

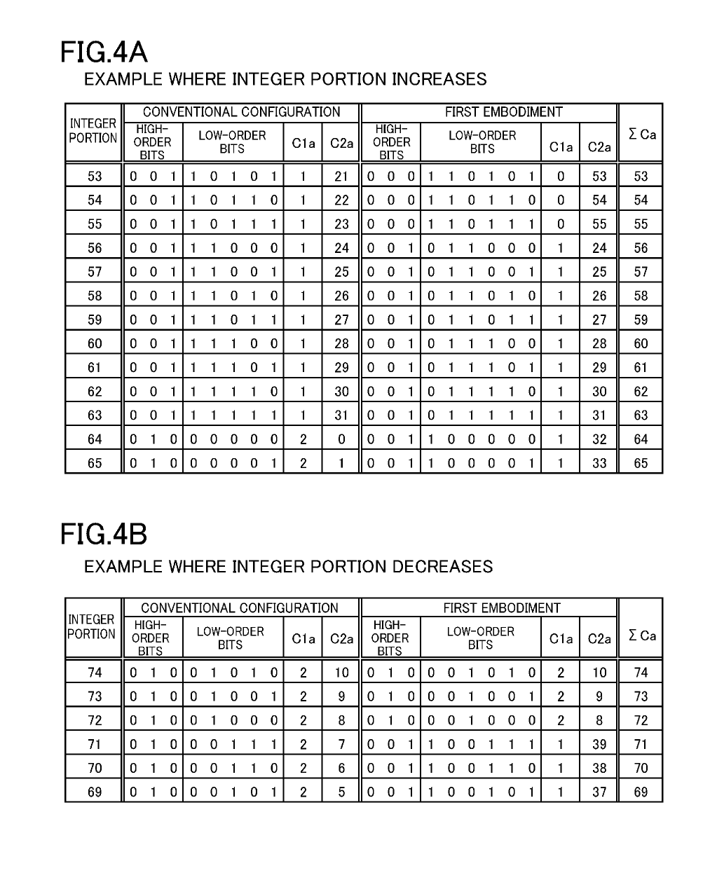

FIGS. 4A and 4B are tables illustrating example control values according to a conventional configuration and this embodiment. In the table, C1 a denotes the number of capacitive elements which are controlled in a high capacitance state among the capacitive elements C1_{—}1-C1_{—}6 forming the capacitive element group 14. The reference character C2a denotes the number of capacitive elements which are controlled in a high capacitance state among the capacitive elements C2_{—}1-C2_{—}63 forming the capacitive element group 15. The value ΣCa is obtained by converting the total capacitance value of the capacitive element groups 14 and 15 to the number of the capacitive elements C2. In the both of the conventional configuration and this embodiment, the capacitive element groups 14 and 15 can be controlled so that the total capacitance value is equal to the integer portion. However, in the conventional configuration, since the integer portion of 8 bits is simply divided into 3 high-order bits and 5 low-order bits, the low-order bits vary in a full range from 5b00000 to 5b11111. On the other hand, in this embodiment, since the redundant MSB is added to the low-order bits, the low-order bits merely vary from 6b001000 to 6b110111, except for the case where the integer portion is lower than the lower limit “32” and higher than the upper limit “223.” That is, the control value of the capacitive element group 15 stabilizes between the lower limit “8” and the upper limit “55” of the low-order bits.

As shown in FIG. 4A, for example, in the conventional configuration, when the integer portion varies from 63 to 64, carry or borrow frequently occurs between the high- and low-order bits. On the other hand, in this embodiment, carry occurs when, for example, the integer portion increases by 1 to vary from 55 to 56. When the integer portion varies to 56, the low-order bits vary to represent 24. Thus, even when the integer portion returns to 55 after that, no borrow occurs and the low-order bits merely vary to represent 23. Also, in this embodiment, as shown in FIG. 4B, borrow occurs when, for example, the integer portion decreases by 1 to vary from 72 to 71. When the integer portion varies to 71, the low-order bits vary to represent 39. Thus, even when the integer portion returns to 72 after that, no carry occurs and the low-order bits merely vary to represent 40.

As described above, according to this embodiment, once carry or borrow between the high- and low-order bits is caused by a variation in the integer portion, the low-order bits vary to a value in a middle of the range. Thus, carry or borrow will hardly occur after that. This improves noise characteristics and linearity of the DCO 10. Furthermore, in this embodiment, since the maximum value of the high-order bits is 3b110, the number of the capacitive elements C1 forming the capacitive element group 14 can be reduced to 6, which is one element less than that of the conventional configuration.

Note that the lower limit “8” and the upper limit “55” of the low-order bits are merely examples, and may be other values including non-integer values. The lower limit “32” and the upper limit “223” of the integer portion, and the value “32” for incrementing and decrementing the low-order bits are corresponding values where the capacitance ratio of the capacitive elements C1 to C2 is 32:1. These values differ depending on the capacitance ratio.

The number of the capacitive elements C1 may be 7 as in the conventional configuration, and the number of the capacitive elements C2 forming the capacitive element group 15 may be less than 63.

### Variation

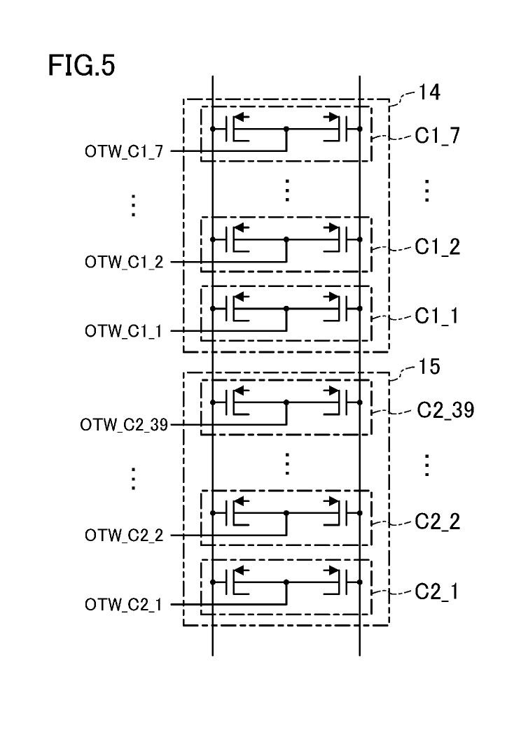

FIG. 5 illustrates a main configuration of a DCO 10 according to a variation. A capacitive element group 14 is formed by coupling 7 capacitive elements C1_{—}1-C1_{—}7 in parallel. A capacitive element group 15 is formed by coupling 39 capacitive elements C2_{—}1-C2_{—}39 in parallel.

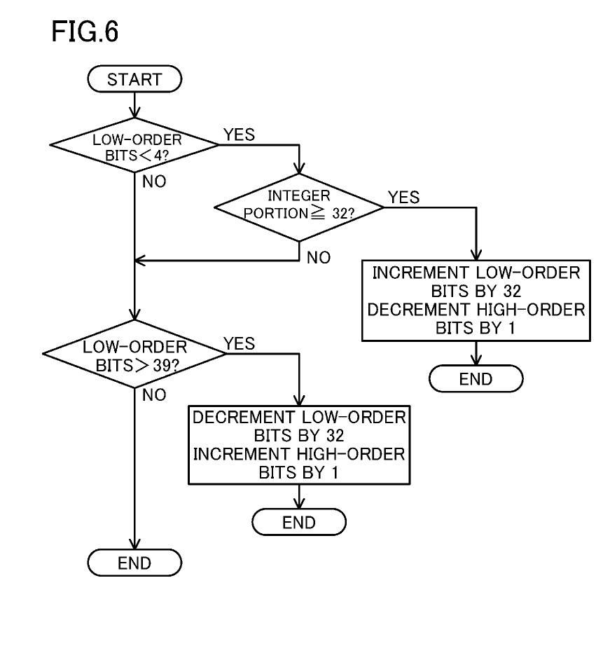

An example operation of an operational circuit 26 according to this variation will be described with reference to FIG. 6. The operational circuit 26 increments low-order bits by N, i.e. 32, and decrements high-order bits by 1 as a borrow operation between the high- and low-order bits when the low-order bits may be lower than a lower limit “4.” When an integer portion is lower than a lower limit “32,” the value of the high-order bits is the minimum value 3b000 and cannot be decremented. The operational circuit 26 performs the processing only when the integer portion is the lower limit “32” or higher. On the other hand, the operational circuit 26 decrements the low-order bits by N, i.e. 32, and increments the high-order bits by 1 as the carry operation between the high- and low-order bits, when the low-order bits may be higher than an upper limit “39.” In this variation, no upper limit is set in the integer portion for the processing. This is because the high-order bits can be at maximum 3b111.

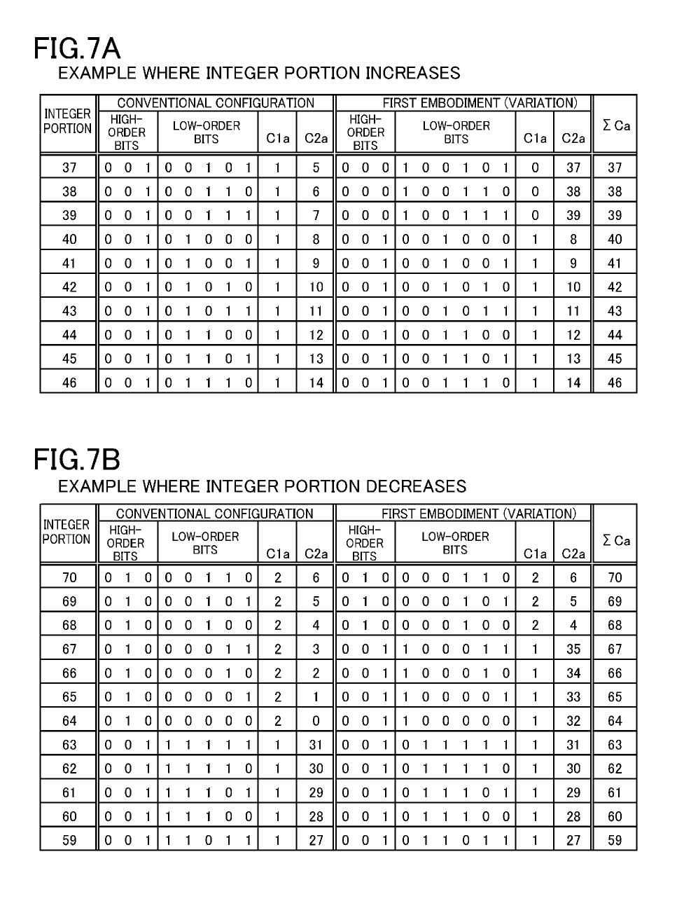

FIGS. 7A and 7B are tables illustrating control values according to the conventional configuration and the variation. In the variation, the low-order bits vary from 6b000100 to 6b100111 only except for the case where the integer portion is lower than the lower limit “32.” That is, the control value of the capacitive element group 15 stabilizes between the lower limit “4” and the upper limit “39” of the low-order bits. As shown in FIG. 7A, for example, in this variation, carry occurs when the integer portion increases by 1 to vary from 39 to 40. When the integer portion varies to 40, the low-order bits vary to represent 8. Thus, even when the integer portion returns to 39 after that, no borrow occurs and the low-order bits merely vary to represent 7. Also, in this variation, as shown in FIG. 7B, borrow occurs when, for example, the integer portion decreases by 1 to vary from 68 to 67. When the integer portion varies to 67, the low-order bits vary to represent 35. Thus, even when the integer portion returns to 68 after that, no carry occurs and the low-order bits merely vary to represent 36.

In this variation, since the control value of the capacitive element group 15 is “39” at maximum, the number of the capacitive elements C2 is reduced to 39 to minimize the area occupied by the capacitive element group 15. That is, the minimum number of the capacitive elements C2 is equal to the upper limit (the value obtained by rounding the upper limit, where the upper limit is not an integer) of the low-order bits.

When the variation range of the integer portion is within the difference between the variable range of the low-order bits provided by the expression, the upper limit of the low-order bits—the lower limit of the low-order bits +1, and a ratio of weight of the high-order bits to the low-order bits (in this variation, (39−4+1)−32=4), no further carry or borrow occurs once carry or borrow has occurred and the low-order bits have varied to represent 8 or 35. When the variation range of the integer portion exceeds the difference, further carry or borrow may occur. That is, the difference between the variable range of the low-order bits and the ratio of weight of the high-order bits to the low-order bits can be regarded as a hysteresis margin of the variations in the integer portion. While the configuration of FIG. 2 requires more capacitive elements C2 than that of this variation, the upper limit is “55” and the lower limit is “8,” and the hysteresis margin is thus 16(=(55−8+1)−32). Therefore, the configuration of FIG. 2 is more resistant to the variations in the integer portion than that of this variation. On the other hand, when reduction in the circuit area and power consumption is important, the hysteresis margin can be 1. In this case, the lower limit and the upper limit of the low-order bits are 1 and 33, respectively, and the number of the capacitive elements C2 can be reduced to 33.

While in the above description, the operational circuit 26 performs a carry or borrow operation between the high- and low-order bits based on a comparison result between the upper limit or the lower limit, a carry or borrow operation may be performed according to a variation value of the integer portion. Processing examples based on the variation value of the integer portion will be described below.

### First Example

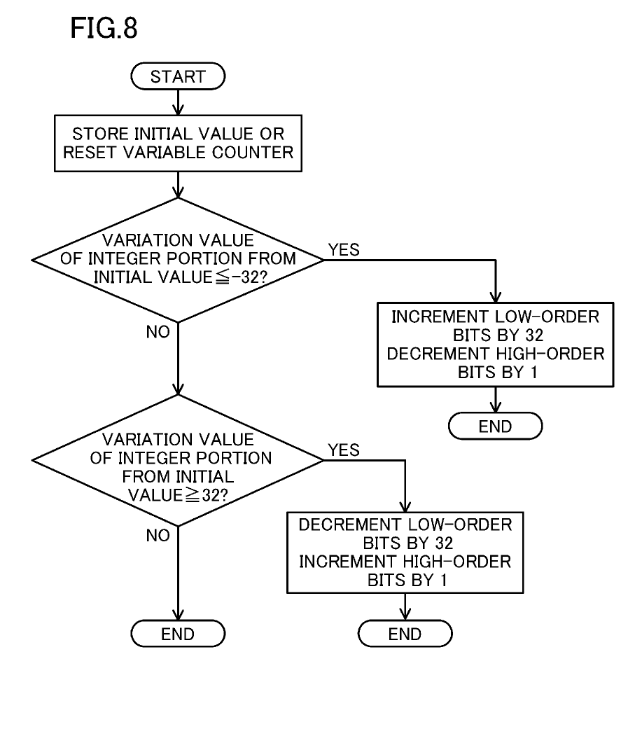

FIG. 8 is a flow chart illustrating an operation of an operational circuit 26 according to a first example. The operational circuit 26 according to this example performs a carry or borrow operation between high- and low-order bits based on a variation value of an integer portion from an initial value. Specifically, the operational circuit 26 stores the initial value of the integer portion, or resets a variable counter, which will be described layer. The operational circuit 26 increments the low-order bits by N, i.e. 32, and decrements the high-order bits by 1 as the borrow operation between the high- and low-order bits, when the integer portion decreases from the initial value by −N, i.e., −32, or more. On the other hand, the operational circuit 26 decrements the low-order bits by N, i.e. 32, and increments the high-order bits by 1 as the carry operation between the high- and low-order bits, when the integer portion increases from the initial value by N, i.e., 32, or more.

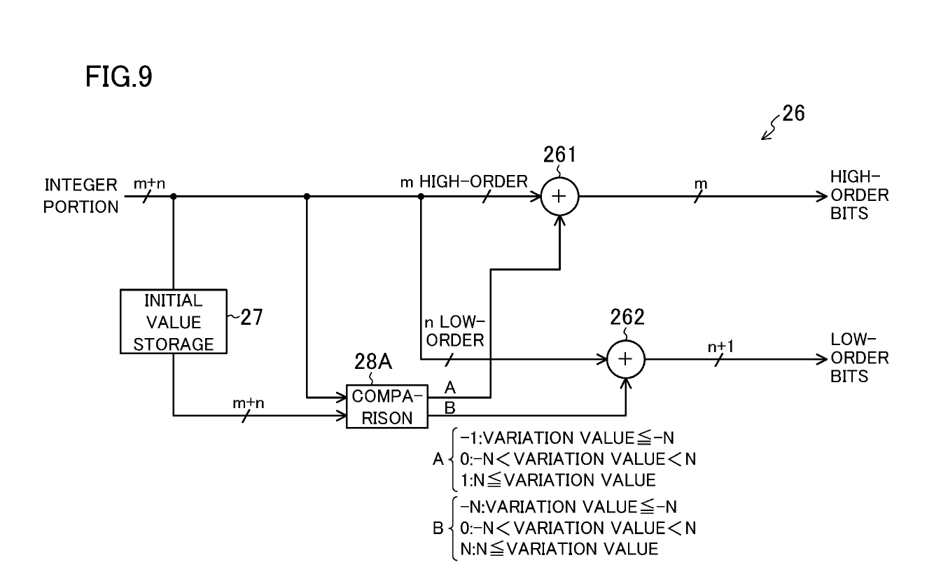

The operational circuit 26 according to this example may be configured as shown in FIG. 9. An initial value storage section 27 stores the initial value of the integer portion with an m+n bit width. A compare section 28A compares the integer portion input to the operational circuit 26 to the initial value stored in the initial value storage section 27 to output values A and B. The value Δ is −1 where the variation value of the integer portion from the initial value is −N or less, 0 where the variation value is higher than −N and lower than N, and 1 where the variation value is N or more. An adder 261 adds m high-order bits of the integer portion to the value Δ and outputs the high-order bits with an m-bit width. The value B is −N where the variation value of the integer portion from the initial value is −N or less, and 0 where the variation value is higher than −N and lower than N, and N where the variation value is N or more. An adder 262 adds n low-order bits of the integer portion to the value B and outputs the low-order bits with an n+1-bit width.

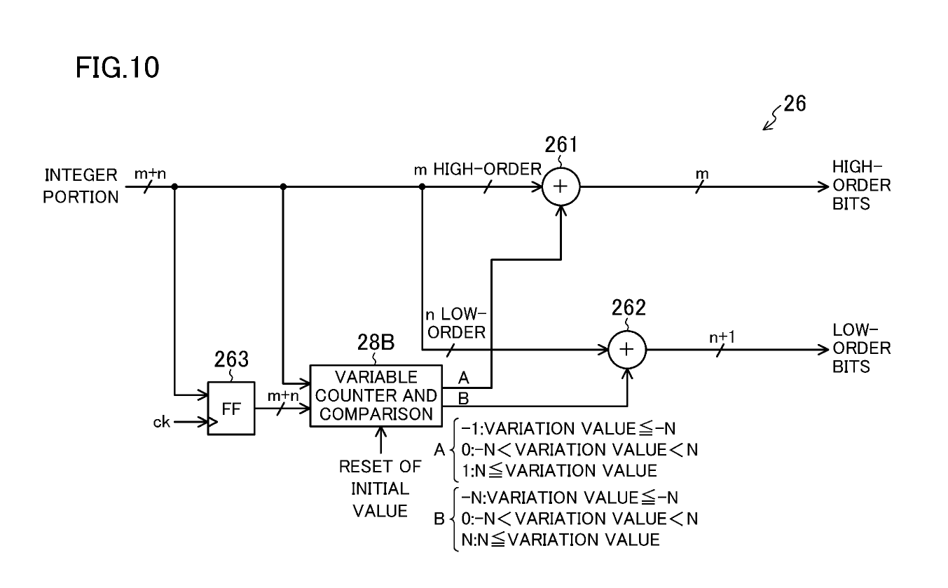

The operational circuit 26 according to this example may be configured as shown in FIG. 10. A flip-flop 263 holds the integer portion with an m+n bit width input to the operational circuit 26 at the timing of a clock signal ck. A variable counter and compare section 28B is reset by an initial reset signal. The difference between the integer portion input to the operational circuit 26 and an output from the flip-flop 263, i.e., the integer portion which has been input one clock earlier is accumulated, and the values A and B are output. Since the output from the flip-flop 263 represents the integer portion one clock earlier, the value accumulated by the variable counter and compare section 28B corresponds to the variation value of the integer portion from the initial value, where the initial value is the integer portion at the time of reset. The values A and B and the operations of the adders 261 and 262 are as described above.

### Second Example

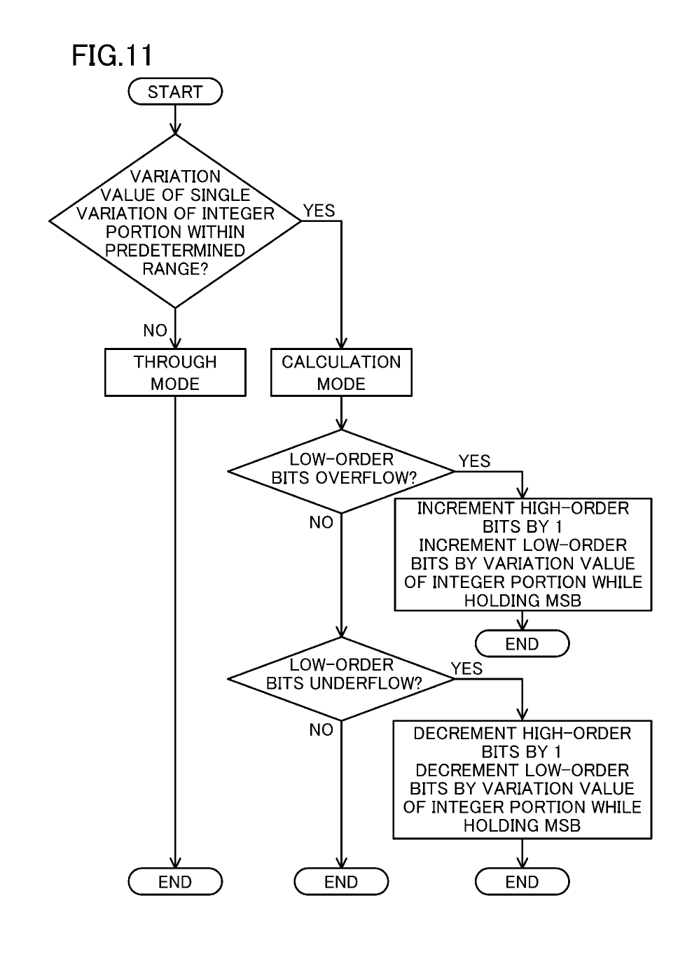

FIG. 11 is a flow chart illustrating an operation of an operational circuit 26 according to a second example. The operational circuit 26 according to this example performs a carry or borrow operation between high- and low-order bits based on a variation value of a single variation in an integer portion. Specifically, the operational circuit 26 operates in a through mode when the variation value of the single variation in the integer portion is out of a predetermined range. Where the bit width of the integer portion is m+n, the operational circuit 26 updates the high-order bits to m high-order bits of the integer portion, the MSB of the low-order bits to zero, and the low-order bits other than the MSB to the n low-order bits of the integer portion in the through mode.

On the other hand, the operational circuit 26 operates in a calculation mode when the variation value of the single variation in the integer portion is within the predetermined range. In the calculation mode, the operational circuit 26 adds the variation value of the integer portion to the low-order bits. Note that, when the low-order bits may overflow, the operational circuit 26 increments the high-order bits by 1 and increments the low-order bits by the variation value of the integer portion while holding the MSB, as the carry operation between the high- and low-order bits. That is, in the operation of the low-order bits, no carry operation is performed between the MSB and the bits lower than the MSB. When the low-order bits may underflow, the operational circuit 26 decrements the high-order bits by 1 and decrements the low-order bits by the variation value of the integer portion while holding the MSB, as the borrow operation between the high- and low-order bits. That is, in the operation of the low-order bits, no borrow operation is performed between the MSB and the bits lower than the MSB.

As the predetermined range, for example, ±1 may be set. It is assumed that a variation in the integer portion within ±1 is caused by drift of a frequency synthesizer in a lock state. Thus, when the integer portion varies due to the drift by setting the predetermined range within ±1, the operational circuit 26 is operated in a calculation mode to hardly cause carry or borrow between the high- and low-order bits.

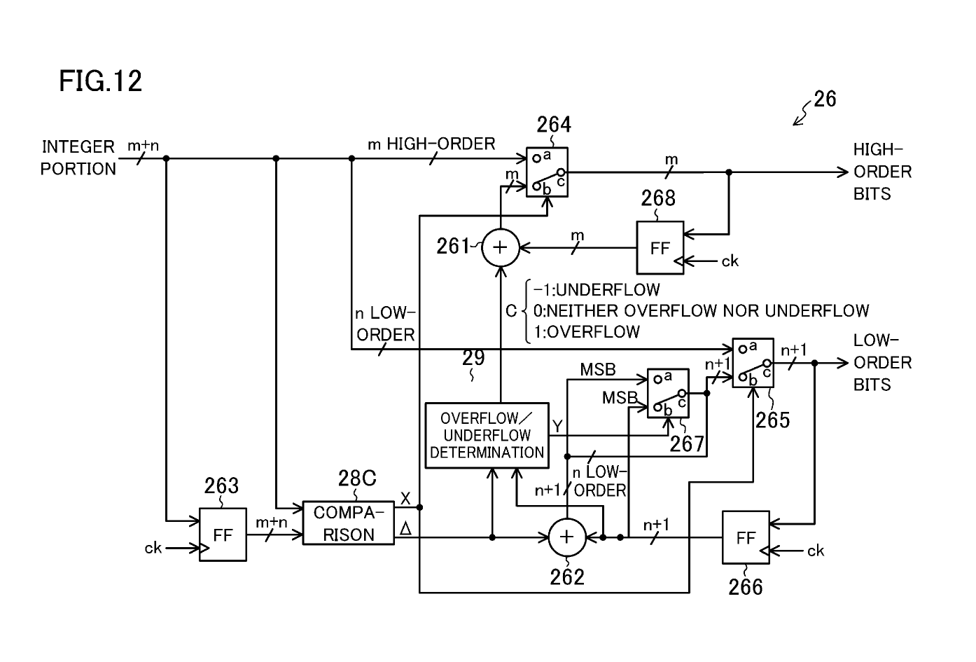

The operational circuit 26 according to this example may be configured as shown in FIG. 12. A flip-flop 263 holds the integer portion with an m+n bit width input to the operational circuit 26 at the timing of the clock signal ck. A compare section 28C compares the integer portion input to the operational circuit 26 to an output from the flip-flop 263, i.e., the integer portion which has been input one clock earlier, and outputs a control signal X to control switches 264 and 265, and to output a variation value Δ of a single variation in the integer portion. Specifically, the compare section 28C controls each of the switches 264 and 265 so that a terminal a is coupled to a common terminal c when the single variation in the integer portion is out of the predetermined range, and so that a terminal b is coupled to the common terminal c when the single variation in the integer portion is within the predetermined range.

A flip-flop 266 holds the low-order bits with an n+1-bit width at the timing of the clock signal ck. An overflow/underflow determination section (hereinafter simply referred to as a “determination section”) 29 receives the variation value Δ and an output from the flip-flop 266 and sums the values to determine whether or not the low-order bits overflow/underflow, outputs a control signal Y to control a switch 267, and outputs a value C. Specifically, the determination section 29 controls the switch 267 so that a terminal a is coupled to a common terminal c, when it determines that the low-order bits neither overflow nor underflow, and so that a terminal b is coupled to the common terminal c, when it determines that the low-order bits may overflow or underflow. The value C is −1 where the low-order bits may underflow, 1 where the low-order bits may overflow, and 0 where the low-order bits neither overflow nor underflow.

A flip-flop 268 holds the high-order bits with an n-bit width at the timing of the clock signal ck. An adder 261 adds an output from the flip-flop 268 to the value C. M high-order bits of the integer portion are input to the terminal a of the switch 264. An output from the adder 261 with an m-bit width is input to the terminal b of the switch 264. The high-order bits with an m-bit width are output from the common terminal c of the switch 264.

An adder 262 adds an output from the flip-flop 266 with an n+1-bit width to the variation value Δ. The MSB of an output from the adder 262 is input to the terminal a of the switch 267. The MSB of the output from the flip-flop 266 is input to the terminal b of the switch 267. N low-order bits of the integer portion are input to the terminal a of the switch 265. A value with an n+1-bit width, which is obtained by adding, as the MSB, a value of 1 bit output from the common terminal c of the switch 267 to n low-order bits of an output from the adder 262, is input to the terminal b of the switch 265. The low-order bits with an n+1-bit width is output from the common terminal c of the switch 265.

### Third Example

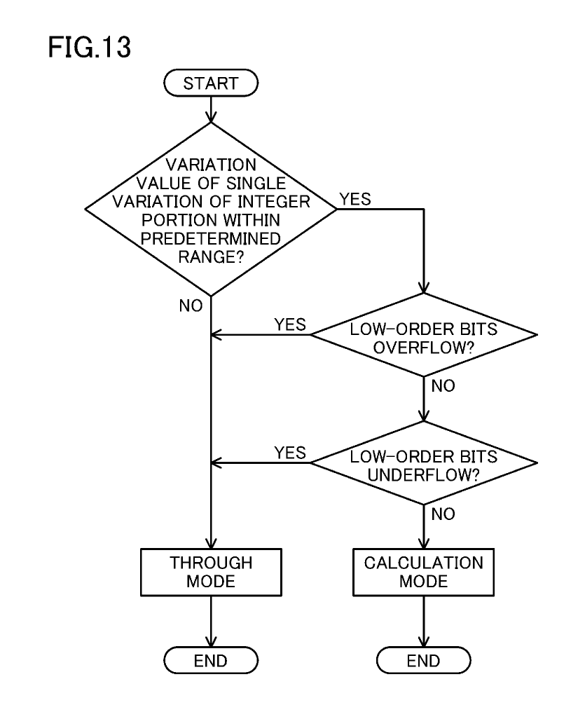

FIG. 13 is a flow chart illustrating an operation of an operational circuit 26 according to a third example. The operational circuit 26 according to this example performs a carry or borrow operation between high- and low-order bits based on a variation value of a single variation in the integer portion. Specifically, the operational circuit 26 operates in a through mode when the variation value of the single variation in the integer portion is out of a predetermined range, or when the variation value of the single variation in the integer portion is within the predetermined range and the low-order bits may overflow or underflow, and operates in a calculation mode in other cases. The through mode and the operate mode are as described above. The predetermined range is preferably set, for example, within ±1 as described above.

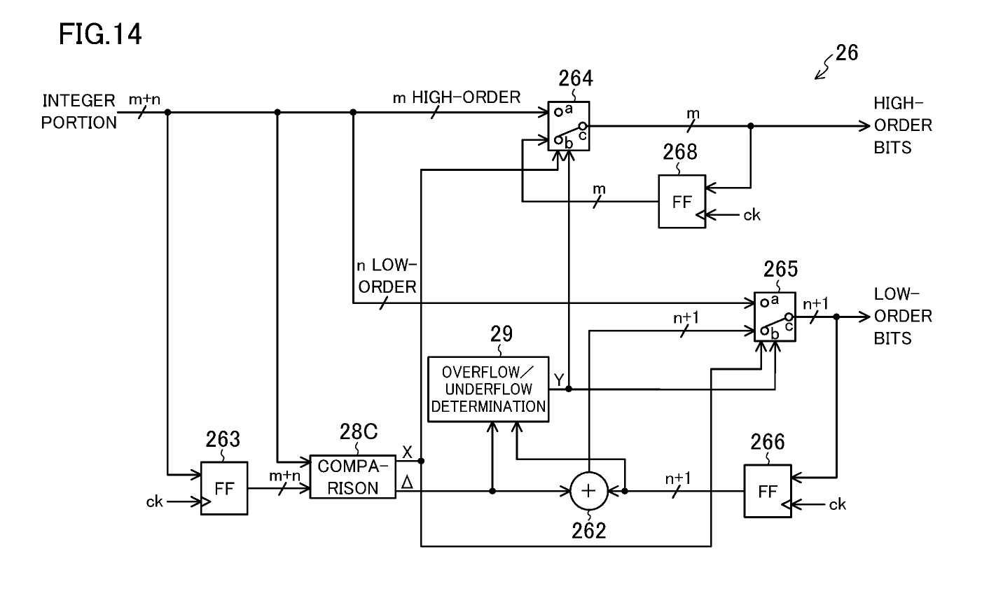

The operational circuit 26 according to this example may be configured as shown in FIG. 14. The configuration shown in FIG. 14 is similar to the configuration of the operational circuit 26 in FIG. 12 but the adder 261 and the switch 267 are omitted. However, different from FIG. 12, an output from the flip-flop 268 with an m-bit width is input to the terminal b of the switch 264. An output from the adder 262 with an n+1-bit width is input to the terminal b of the switch 265. Moreover, the switches 264 and 265 are controlled by the control signal Y output from the determination section 29. Specifically, the determination section 29 controls the switches 264 and 265 so that the terminal a is coupled to the common terminal c when it has determined that the low-order bits may overflow or underflow, and so that the terminal b is coupled to the common terminal c when it has determined that the low-order bits neither overflow nor underflow.

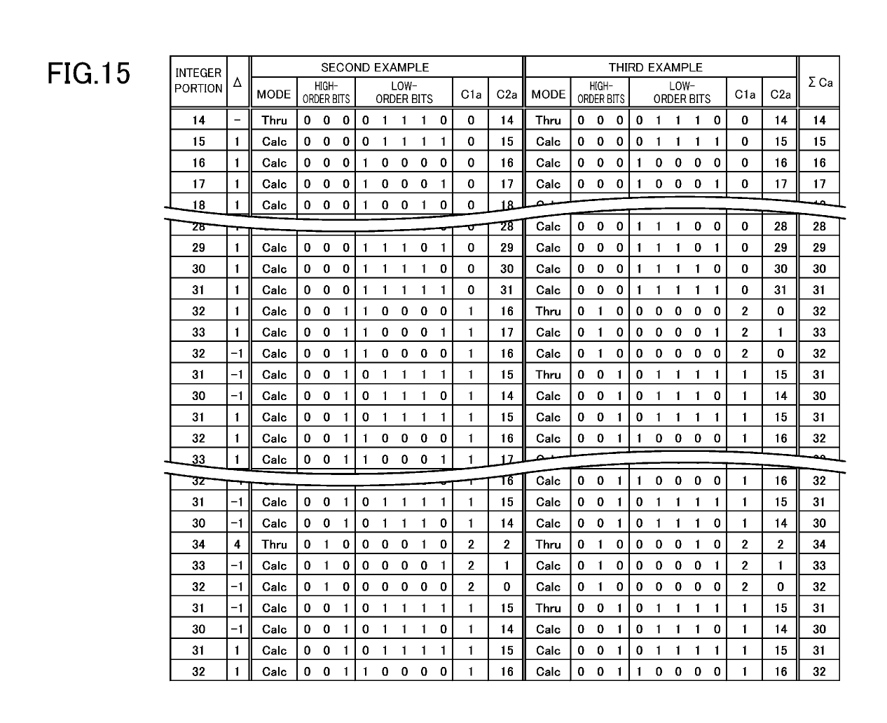

FIG. 15 is a table illustrating control values according to the second and third examples. The bit width of the integer portion is 7 bits, the bit width of the high-order bits is 3 bit, and the bit width of the low-order bits is 5 bits. First, when 14 is input as an integer portion, the operational circuit 26 operates in the through mode (Thru) both in the second and third examples. At this time, the high-order bits are set to 3b000, and the low-order bits are set to 5b01110. After that, when the integer portion increases one by one like 15→16→17→ . . . , the operational circuit 26 operates in the calculation mode (Calc) and increments the low-order bits by 1 both in the second and third examples. When the integer portion is 31, the low-order bits are the maximum value 5b11111. Then, the integer portion further increases by 1, the low-order bits overflow. Thus, in the second example, the high-order bits are incremented by 1, and the low-order bits are incremented by the variation value “1” of the integer portion while holding the MSB. The high-order bits are updated to 3b001, and the low-order bits are updated to 5b10000 which is the middle of the range. Therefore, even when the integer portion varies then within the variation range of “±1” from 30 to 33, the high-order bits do not vary, and only the low-order bits vary.

On the other hand, in the third example, when the integer portion further increases by 1 from the state where the low-order bits are the maximum value 5b11111, the operational circuit 26 operates in the through mode to update the high-order bits to 3b010, and the low-order bits to 5b00000. That is, carry occurs between the high- and low-order bits. However, when the integer portion varies then from 33 to 32, the low-order bits neither overflow nor underflow, and thus, the operational circuit 26 operates in the calculation mode and only the low-order bits vary. When the integer portion is 32, the low-order bits are the minimum value 5b00000. Then, when the integer portion decreases by 1, the low-order bits underflow, and thus the operational circuit 26 operates in the through mode to update the high-order bits to 3b001 and the low-order bits to 5b01111 in the third example. That is, borrow occurs between the high- and low-order bits. However, when the integer portion varies then within the variation range of “±1” from 30 to 33, the high-order bits do not vary and only the low-order bits vary.

When the variation value of the integer portion exceeds ±1, for example, when the integer portion varies from 30 to 34, the operational circuit 26 operates in the through mode both in the second and third examples. At this time, the high-order bits are updated to 3b010, and the low-order bits are updated to 5b00010. Then, in the second example, even when the integer portion varies within the variation value “±1” from 30 to 33, the high-order bits do not vary and only the low-order bits vary. On the other hand, in the third example, when the integer portion varies from 32 to 31, the operational circuit 26 once operates in the through mode. Even when the integer portion varies then within the variation range of “±1” from 30 to 33, the high-order bits do not vary and the low-order bits vary.

As described above, as compared to the second example, the third example provides a simple circuit configuration. On the other hand, in the third example, since the operational circuit 26 often operates in the through mode, causing carry or borrow often occurs between the high- and low-order bits. However, in both the second and third examples, once carry or borrow occurs between the high- and low-order bits, further carry or borrow hardly occurs to improve noise characteristics and linearity of the DCO 10.

### Second Embodiment

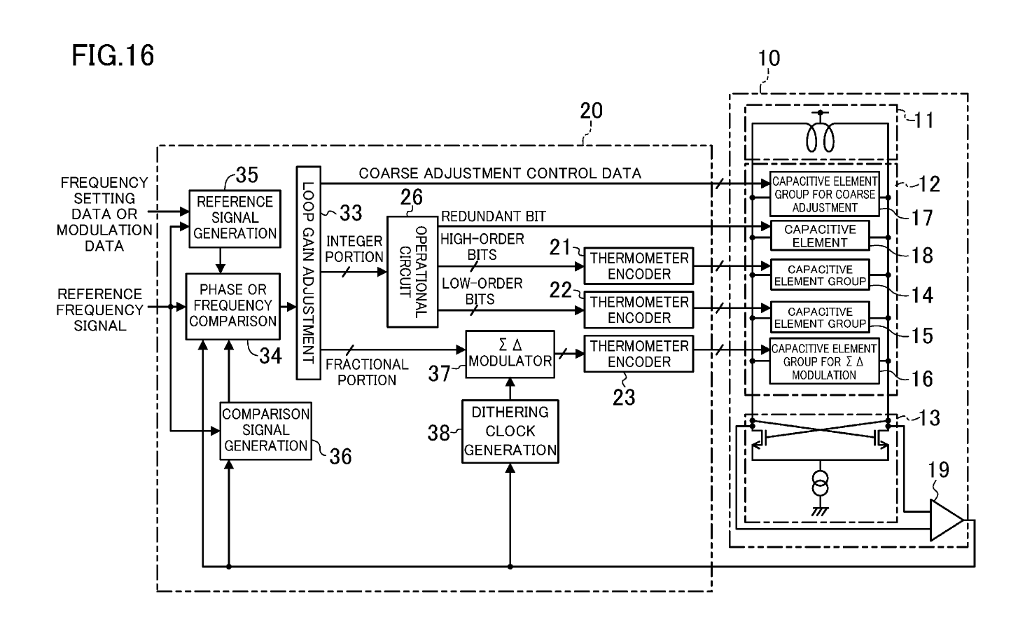

FIG. 16 illustrates a configuration of a frequency synthesizer according to a second embodiment. The frequency synthesizer according to this embodiment is similar to the frequency synthesizer according to the first embodiment, but further includes a capacitive element 18 in the DCO 10. Differences from the first embodiment will be described below.

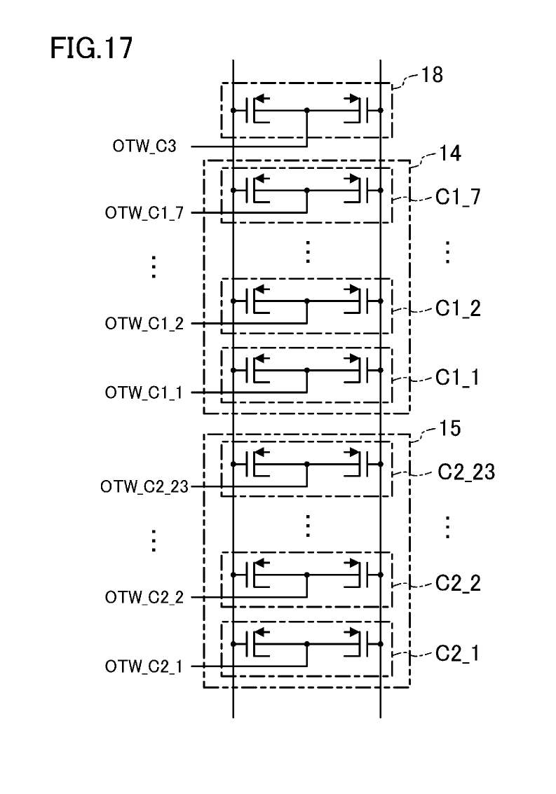

An operational circuit 26 divides an input integer portion into high-order bits and low-order bits in a ratio of weight of N:1, e.g., 32:1, and generates a redundant bit controlling the capacitive element 18. N is a value represented by 2ⁿ where the bit width of the low-order bits is n. FIG. 17 illustrates a main configuration of the DCO 10. A capacitive element group 14 is formed by coupling 7 capacitive elements C1_{—}1-C_{—}7 in parallel. A capacitive element group 15 is formed by coupling 23 capacitive elements C2_{—}1-C2_{—}23. A capacitive element 18 is switched between a high capacitance value C_{H3} and a low capacitance value C_{L3} according to a redundant bit (a control signal OTW_C3). The ratio of the difference between C_{H1} and C_{L1} to the difference between C_{H3} and C_{L3} is 2:1. That is, the capacitance value of the capacitive element 18 is 16 times the capacitance value of each of the capacitive elements C2, and half the capacitance value of each of the capacitive elements C1.

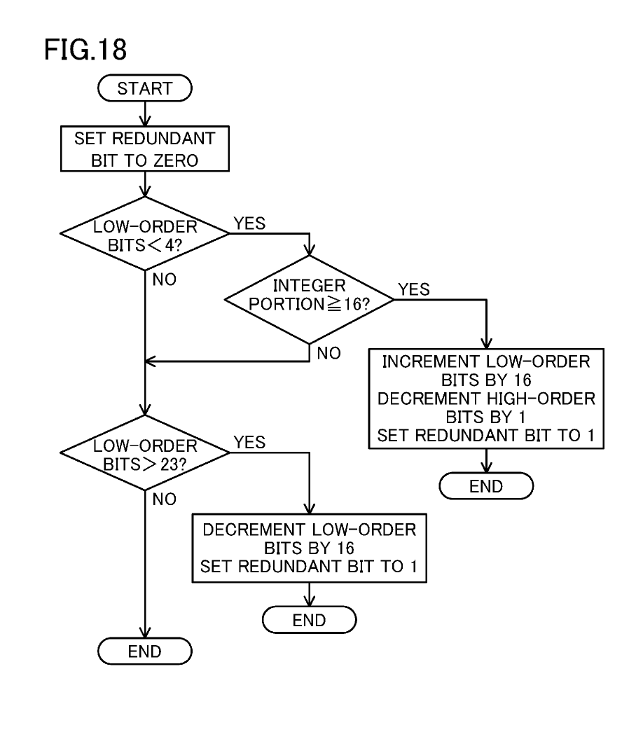

An example operation of the operational circuit 26 will be described with reference to the flow chart of FIG. 18. The capacitive element 18 is in a low-capacitance state where the redundant bit is 0, and in a high capacitance state where the redundant bit is 1. The operational circuit 26 sets the redundant bit to 0 first. When, the low-order bits represent a value lower than a lower limit “4,” the operational circuit 26 increments the low-order bits by N/2, i.e., 16, decrements the high-order bits by 1, and sets the redundant bit to 1. Where the integer portion is lower than a lower limit “16,” the high-order bits are the minimum value 3b000 and cannot be decremented. Thus, the operational circuit 26 performs the processing only when the integer portion is the upper limit “16” or more. On the other hand, when the low-order bits represent a value higher than an upper limit “23,” the operational circuit 26 decrements the low-order bits by N/2, i.e., 16, and sets the redundant bit to 1.

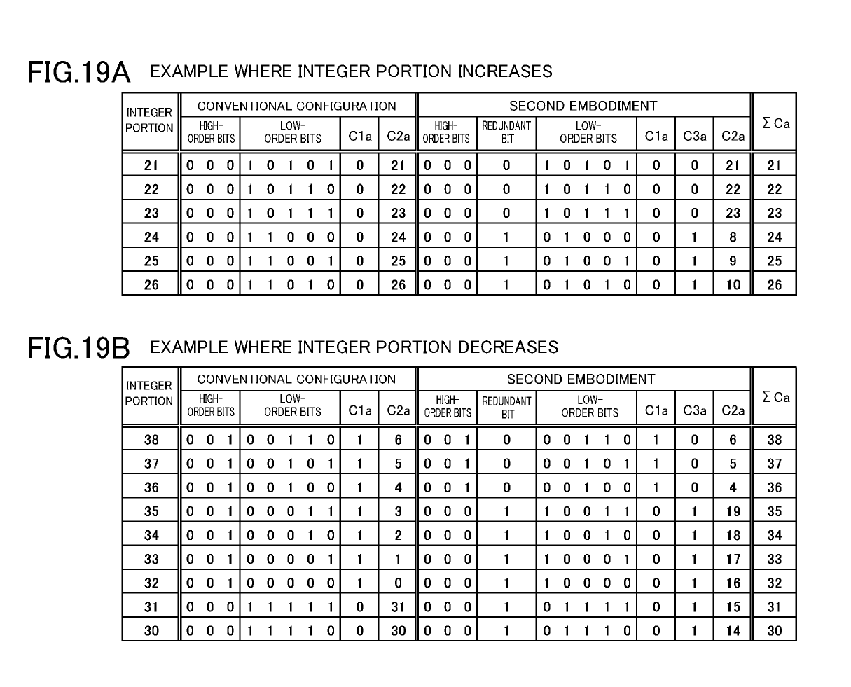

FIGS. 19A and 19B are tables illustrating example control values according to the conventional configuration and this embodiment. In this embodiment, the low-order bits merely vary from 5b00100 to 5b10111 other than the case where the integer portion represents a value lower than the lower limit “16.” That is, the control value of the capacitive element group 15 stabilizes between the lower limit “4” and the upper limit “23” of the low-order bits. As shown in FIG. 19A, in this embodiment, carry occurs when, for example, the integer portion increases by 1 to vary from 23 to 24. When the integer portion varies to 24, the redundant bit varies to 1, and the low-order bits vary to represent 8. Thus, even when the integer portion returns to 23 after that, no borrow occurs and the low-order bits merely vary to represent 7. Also, in this embodiment, as shown in FIG. 19B, borrow occurs when, for example, the integer portion decreases by 1 to vary from 36 to 35. When the integer portion varies to 35, the redundant bit varies to 1, and the low-order bits vary to represent 19. Thus, when the integer portion returns to 36 after that, no carry occurs and the low-order bits merely vary to 20.

The hysteresis margin in this embodiment is the difference between the available range of the low-order bits obtained by adding 1 to the difference between the upper limit and the lower limit of the low-order bits and a half of the ratio of weight of the high-order bits to the low-order bits, and the value is 4 (=(23−4+1)−32/2). That is, in this embodiment, the hysteresis margin equivalent to that in the variation of the first embodiment is reliably provided to reduce the circuit area and power consumption as mush as possible. The hysteresis margin may be determined as appropriate in view of the circuit area, the power consumption, and variations in the integer portion.

As described above, similar to the first embodiment, carry or borrow hardly occurs between the high- and low-order bits of the integer portion in this embodiment. This improves noise characteristics and linearity of the DCO 10, and sufficiently provides a DEM effect when the thermometer encoder 22 has a DEM function.

Note that the lower limit “4” and the upper limit “23” of the low-order bits are merely examples, and may be other values including non-integer values. The lower limit “16” of the integer portion and the value “16” for incrementing and decrementing the low-order bits are corresponding values where the capacitance ratio of the capacitive elements C1 to C2 is 32:1. These values differ depending on the capacitance ratio.

In both the first and second embodiments, the thermometer encoder 22 may have a DEM function. In the both embodiments, since the hysteresis margin of the low-order bits is reliably provided, a DEM effect can be sufficiently obtained. This improves the linearity of the DCO 10, and improves modulation accuracy particularly when the frequency synthesizer is used as a modulator temporally changing a frequency.

The number of the capacitive elements C1 forming the capacitive element group 14 may be more than 7, and the thermometer encoder 21 may have a DEM function. Alternatively, only the capacitive element group 15 of the low-order bits may have a DEM function while the capacitive element group 14 has no advantage of reducing the area and currents and the same elements are used. Therefore, the capacitance ratio of the capacitive elements C1 to C2 may be 1:1, i.e., the ratio of the difference between C_{H1} and C_{L1} to the difference between C_{H2} and C_{L2} may be 1:1.

What is claimed is:

1. A frequency synthesizer comprising:
a control circuit configured to generate a digital control signal; and
a digitally controlled oscillator of which oscillation frequency changes according to the generated digital control signal, wherein
the control circuit includes
an operational circuit configured to divide an integer portion of a numerical value representing a phase difference between a reference signal and an oscillation frequency signal of the digitally controlled oscillator into high-order bits and low-order bits including a redundant bit as an MSB,
a first encoder configured to encode the high-order bits to generate a first control signal, and
a second encoder configured to encode the low-order bits to generate a second control signal,
the digitally controlled oscillator includes
a first capacitive element group formed by coupling in parallel, a plurality of first capacitive elements which are switchable between high and low capacitance states, and having a capacitance value controlled by the first control signal, and
a second capacitive element group formed by coupling in parallel, a plurality of second capacitive elements which are switchable between high and low capacitance states, and having a capacitance value controlled by the second control signal, and
the oscillation frequency of the digitally controlled oscillator changes according to a total capacitance value of the first and second capacitive element groups.

2. The frequency synthesizer of claim 1, wherein
where a weight of the high-order bits to the low-order bits is N, the operational circuit increments the low-order bits by N and decrements the high-order bits by 1 when the low-order bits may be lower than a lower limit, and decrements the low-order bits by N and increments the high-order bits by 1 when the low-order bits may be higher than an upper limit.

3. The frequency synthesizer of claim 1, wherein
where a weight of the high-order bits to the low-order bits is N, the operational circuit increments the low-order bits by N and decrements the high-order bits by 1 when the integer portion decreases from an initial value by N or more, and decrements the low-order bits by N and increments the high-order bits by 1 when the integer portion increases from the initial value by N or more.

4. The frequency synthesizer of claim 1, wherein
where a bit width of the integer portion is m+n bits, the operational circuit operates
in a through mode when a variation value of a single variation in the integer portion is out of a predetermined range, the through mode being for updating the high-order bits to m high-order bits of the integer portion, the MSB of the low-order bits to zero, and the low-order bits other than the MSB to n low-order bits of the integer portion, and
in a calculation mode when the variation value is within the predetermined range, the calculation mode being for incrementing the high-order bit by 1 and incrementing the low-order bits by the variation value while holding the MSB when the low-order bits may overflow, and for decrementing the high-order bits by 1 and decrementing the low-order bits by the variation value while holding the MSB when the low-order bits may underflow.

5. The frequency synthesizer of claim 1, wherein
where a bit width of the integer portion is m+n bits, the operational circuit operates
in a through mode when a variation value of a single variation in the integer portion is out of a predetermined range, or when the variation value is within the predetermined range and the low-order bits may overflow or underflow, the through mode being for updating the high-order bits to m high-order bits of the integer portion, the MSB of the low-order bits to zero, and the low-order bits other than the MSB to n low-order bits of the integer portion, and
in a calculation mode in other cases, the calculation mode being for adding the variation value to the low-order bits.

6. The frequency synthesizer of claim 1, wherein
where a weight of the high-order bits to the low-order bits is N, a number of the second capacitive elements is smaller than 2N−1.

7. The frequency synthesizer of claim 2, wherein
a difference between the lower limit and the upper limit is N or more, and
a number of the second capacitive elements is equal to a value obtained by rounding the upper limit.

8. The frequency synthesizer of claim 1, wherein
a number of the first capacitive elements is 2^{U}−2, where U is a bit width of the high-order bits.

9. A frequency synthesizer comprising:
a control circuit configured to generate a digital control signal; and
a digitally controlled oscillator of which oscillation frequency changes according to the generated digital control signal, wherein
the control circuit includes
an operational circuit configured to divide an integer portion of a numerical value representing a phase difference between a reference signal and an oscillation frequency signal of the digitally controlled oscillator into high-order bits and low-order bits and to generate a redundant bit,
a first encoder configured to encode the high-order bits to generate a first control signal, and
a second encoder configured to encode the low-order bits to generate a second control signal,
the digitally controlled oscillator includes
a first capacitive element group formed by coupling in parallel, a plurality of first capacitive elements which are switchable between high and low capacitance states, and having a capacitance value controlled by the first control signal,
a second capacitive element group formed by coupling in parallel, a plurality of second capacitive elements which are switchable between high and low capacitance states, and having a capacitance value controlled by the second control signal, and
a third capacitive element which is switchable between high and low capacitance states by the redundant bit,
the oscillation frequency of the digitally controlled oscillator changes according to a total capacitance value of the first and second capacitive element groups and the third capacitive element,
a ratio of a difference between a high capacitance value and a low capacitance value of each of the first capacitive elements to a difference between a high capacitance value and a low capacitance value of the third capacitive element is 2:1, and
where a weight of the high-order bits to the low-order bits is N, the operational circuit
increments the low-order bits by N/2, decrements the high-order bits by 1, and sets the redundant bit to a value so that the third capacitive element is in the high capacitance state when the low-order bits may be lower than a lower limit, and
decrements the low-order bits by N/2 and sets the redundant bit to a value so that the third capacitive element is in the high capacitance state when the low-order bits may be higher than an upper limit.

10. The frequency synthesizer of claim 9, wherein
a number of the second capacitive elements is smaller than N−1.

11. The frequency synthesizer of claim 9, wherein
a difference between the lower limit and the upper limit is N/2 or more, and
a number of the second capacitive elements is equal to a value obtained by rounding the upper limit.

12. The frequency synthesizer of claim 1, wherein
where a weight of the high-order bits to the low-order bits is N:1, a ratio of a difference between a high capacitance value and a low capacitance value of each of the first capacitive elements to a difference between a high capacitance value and a low capacitance value of each of the second capacitive elements is N:1.

13. The frequency synthesizer of claim 9, wherein
where a weight of the high-order bits to the low-order bits is N:1, a ratio of a difference between a high capacitance value and a low capacitance value of each of the first capacitive elements to a difference between a high capacitance value and a low capacitance value of each of the second capacitive elements is N:1.

14. The frequency synthesizer of claim 1, wherein
a ratio of a difference between a high capacitance value and a low capacitance value of each of the first capacitive elements to a difference between a high capacitance value and a low capacitance value of each of the second capacitive elements is 1:1.

15. The frequency synthesizer of claim 9, wherein
a ratio of a difference between a high capacitance value and a low capacitance value of each of the first capacitive elements to a difference between a high capacitance value and a low capacitance value of each of the second capacitive elements is 1:1.

16. The frequency synthesizer of claim 1, wherein
the second encoder encodes the low-order bits by dynamic element matching to appropriately switch some of the plurality of second capacitive elements to be set to a high capacitance value and some of the plurality of second capacitive elements to be set to a low capacitance value.

17. The frequency synthesizer of claim 9, wherein
the second encoder encodes the low-order bits by dynamic element matching to appropriately switch some of the plurality of second capacitive elements to be set to a high capacitance value and some of the plurality of second capacitive elements to be set to a low capacitance value.

18. The frequency synthesizer of claim 1, wherein
the first encoder encodes the high-order bits by dynamic element matching to appropriately switch some of the plurality of first capacitive elements to be set to a high capacitance value and some of the plurality of first capacitive elements to be set to a low capacitance value.

19. The frequency synthesizer of claim 9, wherein
the first encoder encodes the high-order bits by dynamic element matching to appropriately switch some of the plurality of first capacitive elements to be set to a high capacitance value and some of the plurality of first capacitive elements to be set to a low capacitance value.
